(19) United States
(12) Patent Application Publication
(10) Pub. No.: US 2025/0151438 A1
(43) Pub. Date: May 8, 2025

(54) COLOR-ROUTING ELEMENT, METHOD OF MANUFACTURING THE SAME, AND IMAGE SENSOR INCLUDING THE COLOR-ROUTING ELEMENT

(71) Applicant: SAMSUNG ELECTRONICS CO., LTD., Suwon-si (KR)

(72) Inventors: Jongwoo HONG, Suwon-si (KR); Changhyun KIM, Seoul-si (KR); Byoungho LEE, Seoul-si (KR); Youngjin KIM, Seoul-si (KR); Gun-Yeal LEE, Seoul-si (KR); Junhyeok JANG, Seoul-si (KR); Yoonchan JEONG, Seoul-si (KR)

(73) Assignees: SAMSUNG ELECTRONICS CO., LTD., Suwon-si (KR); Seoul National University R&DB FOUNDATION, Seoul (KR)

(21) Appl. No.: 18/937,958

(22) Filed: Nov. 5, 2024

(30) Foreign Application Priority Data
Nov. 6, 2023 (KR) 10-2023-0152079
May 21, 2024 (KR) 10-2024-0065859

(51) Int. Cl. H01L 27/146; G06F 30/23

(52) U.S. Cl. CPC H10F 39/8063; G06F 30/23; H10F 39/024; H10F 39/182

(57) ABSTRACT

A method of manufacturing a color-routing element, may include: generating an initial pattern; performing blurring on the initial pattern to generate a reference pattern; performing edge detection on the reference pattern to generate at least one comparison pattern reflecting a process error; performing a simulation to obtain at least one color-routing figure of merit based on the reference pattern and the at least one comparison pattern; updating the initial pattern based on a calculation result of the at least one color-routing figure of merit; generating the updated initial pattern as a target pattern of the color-routing element; and manufacturing the color-routing element based on the target pattern.

### CROSS-REFERENCE TO RELATED APPLICATIONS

This application is based on and claims priority under 35 U.S.C. § 119 to Korean Patent Application Nos. 10-2023-0152079, filed on Nov. 6, 2023, and 10-2024-0065859, filed on May 21, 2024, in the Korean Intellectual Property Office, the disclosures of which are incorporated by reference herein in their entireties.

### BACKGROUND

### 1. Field

The disclosure relates to an image sensor, and more particularly, to a color-routing element, a method of manufacturing the color-routing element, and an image sensor including the color-routing element.

### 2. Description of Related Art

Image sensors typically include microlens arrays, red, green, and blue (RGB) color filters, and photodiodes. The microlens array focuses light onto the photodiode, and the color filter detects the color of incident light. However, the color filter absorbs light of colors other than the light of the corresponding color, and thus, light use efficiency may deteriorate. For example, when an RGB color filter is used, only ⅓ of the incident light is transmitted and the remaining ⅔ of the incident light is absorbed and discarded. Accordingly, the light use efficiency is only about 33%. That is, most of the light loss in the image sensor occurs in the color filter. In particular, when the size of the pixel is reduced to the micrometer level (e.g., deep submicron pixels), the amount of light transmitted via the color filter further decreases. Accordingly, the image sensor becomes vulnerable to noise.

### SUMMARY

Accordingly, the following method are being attempted. The image sensor does not use a color filter that absorbs or blocks light outside a target wavelength range, but uses a color-routing element including nanostructures (or nano posts) so as to separate colors so that each color gathers at a focus of a target pixel.

The disclosure provides a color-routing element, a method of manufacturing the same, and an image sensor including the color-routing element, wherein the color-routing element is manufactured by reflecting a color-routing figure of merit and a process error in a production process thereof and may thus exhibit high color-routing efficiency and light use efficiency and also obtain robustness against the process error.

The technical objects of the disclosure are not limited to the technical objects mentioned above, and other technical objects not described herein are clearly understood by those skilled in the art from the following descriptions.

According to one or more example embodiments, a method of manufacturing a color-routing element, may include: generating an initial pattern; performing blurring on the initial pattern to generate a reference pattern; performing edge detection on the reference pattern to generate at least one comparison pattern reflecting a process error; performing a simulation to obtain at least one color-routing figure of merit based on the reference pattern and the at least one comparison pattern; updating the initial pattern based on a calculation result of the at least one color-routing figure of merit; generating the updated initial pattern as a target pattern of the color-routing element; and manufacturing the color-routing element based on the target pattern.

According to one or more example embodiments, a color-routing element may include: a spacer layer; and a nanostructure array comprising a target pattern repeatedly disposed on the spacer layer and configured to route light, which passes through the color-routing element, to a pixel corresponding to a wavelength. The target pattern may include a plurality of nanostructures disposed in a freeform based on a calculation result of at least one color-routing figure of merit.

According to one or more example embodiments, an image sensor may include: a light detector comprising a plurality of light detection cells configured to sense light; and a color-routing element configured to focus the light on a light detection cell corresponding to a wavelength, among the plurality of light detection cells, by using a nanostructure array disposed above the light detector. A plurality of nanostructures in the nanostructure array may be disposed in a freeform without regularity in size, spacing, and arrangement, based on at least one color-routing figure of merit. The at least one color-routing figure of merit may be obtained by performing, on a reference pattern and at least one comparison pattern of the nanostructure array, an electromagnetic field simulation based on an automatic differentiation technique. The at least one comparison pattern may represent at least one pattern generated by reflecting a process error occurring during a process of producing the color-routing element. The reference pattern may represent a pattern generated to satisfy a condition of a target line width having a minimum size during the process of producing the color-routing element.

According to one or more example embodiments, an image sensor may include: a light detector comprising at least a first pixel configured to sense first wavelength light and a second pixel configured to sense second wavelength light; and a color-routing element configured to: receive light comprising at least the first wavelength light and the second wavelength light; and using a nanostructure array, route the first wavelength light to the first pixel and route the second wavelength light to the second pixel. The nanostructure array may include a plurality of non-regularly shaped nanostructures having irregular geometric shapes.

### BRIEF DESCRIPTION OF THE DRAWINGS

Embodiments will be more clearly understood from the following detailed description taken in conjunction with the accompanying drawings in which:

FIG. 1 is a block diagram of an image sensor according to one or more embodiments;

FIG. 2 illustrates an example of pixel arrangement of a pixel array in an image sensor according to one or more embodiments;

FIG. 3 is a conceptual diagram schematically showing a structure and operation of a color-routing element according to one or more embodiments;

FIG. 4A is a schematic cross-sectional view showing a cross-section of a pixel array in an image sensor according to one or more embodiments;

FIG. 4B is a schematic cross-sectional view showing a cross-section of a pixel array in an image sensor according to one or more embodiments;

FIG. 5 is a plan view schematically showing arrangement of photo-sensing cells in a pixel array of an image sensor according to one or more embodiments;

FIGS. 6A-6C are diagrams comparing elements according to comparative examples to a color-routing element according to one or more embodiments;

FIG. 7 is a diagram illustrating a method of manufacturing a color-routing element according to one or more embodiments;

FIG. 8A shows an example of a target unit pattern of a color-routing element according to one or more embodiments;

FIG. 8B is a graph showing a color-routing effect based on the target unit pattern of FIG. 8A;

FIG. 9 shows an example of a color-routing element including a target unit pattern according to one or more embodiments;

FIG. 10 shows an example of a color-routing element according to one or more embodiments;

FIG. 11 shows an example of a color-routing element according to one or more embodiments;

FIG. 12A shows an example of a comparison unit pattern according to one or more embodiments;

FIG. 12B is a graph showing color-routing efficiency based on the comparison unit pattern of FIG. 12A;

FIG. 13A shows another example of a comparison unit pattern according to one or more embodiments;

FIG. 13B is a graph showing color-routing efficiency based on the comparison unit pattern of FIG. 13A;

FIG. 14 shows a graph comparing color-routing efficiency between a reference unit pattern and a comparison unit pattern according to one or more embodiments;

FIG. 15A shows another example of a target unit pattern according to one or more embodiments;

FIG. 15B is a graph showing color-routing efficiency based on the target unit pattern of FIG. 15A;

FIG. 16 is a diagram illustrating a color-routing function of a color-routing element according to one or more embodiments;

FIG. 17 is a diagram illustrating a comparison result of a color-routing function according to one or more embodiments;

FIG. 18 is a flowchart showing a method of manufacturing a color-routing element, according to one or more embodiments; and

FIG. 19 is a block diagram of an electronic device including an image sensor in which a color-routing element according to one or more embodiments is utilized.

### DETAILED DESCRIPTION

Hereinafter, embodiments are described in detail with reference to the accompanying drawings. Embodiments are illustrated in the drawings and the detailed descriptions thereof are given. However, this is not intended to limit the various embodiments to any particular forms. For example, it is obvious to those skilled in the art that the embodiments can be changed in various ways.

Hereinafter, when an element is described as being “above” or “on” another element, not only may the element be directly above/below/left/right in contact with another element, but also the element may be above/below/left/right in non-contact with another element.

Although terms, such as ‘first’ and ‘second’, may be used to describe various elements, these terms are only used to distinguish one component from other components. These terms are not intended to limit the difference in materials or structures of elements.

The singular forms include the plural forms as well, unless the context clearly indicates otherwise. In addition, when it is described that a part “includes” a certain component, this indicates that the part may further include other components, rather than excluding other components, unless specifically stated to the contrary.

In addition, terms used herein, such as “ . . . part” and “ . . . module” represent a unit that processes functions or operations, which may be provided as hardware or software or as a combination of hardware and software.

The use of the term “the” and other demonstratives similar thereto may correspond to both a singular form and a plural form.

Operations in a method may be performed in any appropriate order, unless explicitly stated that the operations have to be performed in the mentioned order. Also, the use of all exemplary terms (e.g., “etc.” or “and (or) the like”) is only intended to describe a technical concept in detail. Unless limited by the claims, the scope of the disclosure is not necessarily limited by theses exemplary terms.

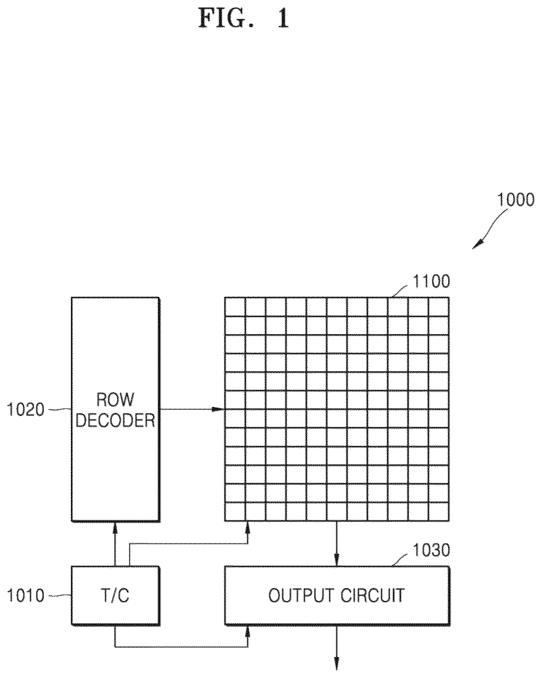

FIG. 1 is a block diagram of an image sensor 1000 according to one or more embodiments.

Referring to FIG. 1, the image sensor 1000 according to one or more embodiments may roughly include a pixel array 1100, a timing controller 1010, a row decoder 1020, and an output circuit 1030. The image sensor 1000 according to one or more embodiments may include a charge coupled device (CCD) image sensor or a complementary metal oxide semiconductor (CMOS) image sensor.

The pixel array 1100 includes a plurality of pixels arranged two-dimensionally in a plurality of rows and a plurality of columns (including a first pixel and a second pixel). The row decoder 1020 selects one row from among the plurality of rows of the pixel array 1100 in response to a row address signal output from the timing controller 1010. The output circuit 1030 outputs light detection signals in units of columns from a plurality of pixels arranged in the selected row. To this end, the output circuit 1030 may include a column decoder and an analog to digital converter (ADC). For example, the output circuit 1030 may include a plurality of ADCs, each of which is located between the column decoder and the pixel array 1100 for each of the columns. Alternatively, the output circuit 1030 may include one ADC located at an output terminal of the column decoder. According to embodiments, the timing controller 1010, the row decoder 1020, and the output circuit 1030 may be provided as a single chip or may be respectively provided as individual chips. A processor for processing the image signal output via the output circuit 1030 may be provided as a single chip together with the timing controller 1010, the row decoder 1020, and the output circuit 1030.

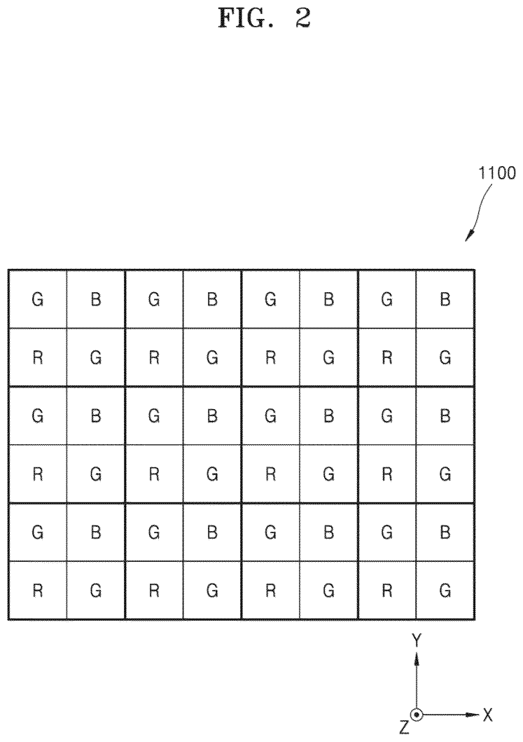

The pixel array 1100 may include a plurality of pixels that sense light of different wavelengths. In other words, a first pixel may correspond to a first wavelength and a second pixel may correspond to a second wavelength. The arrangement of the plurality of pixels that sense light of different wavelengths may be formed in various ways. For example, as described below, FIG. 2 illustrates an example of the pixel arrangement of the pixel array 1100 in the image sensor 1000.

FIG. 2 illustrates an example of pixel arrangement of a pixel array 1100 in an image sensor according to one or more embodiments.

First, FIG. 2 shows a Bayer pattern that is generally adopted in the image sensor 1000. Referring to FIG. 2, one unit pixel includes four quadrant regions, and the first to fourth quadrants may respectively include a blue pixel B, a green pixel G, a red pixel R, and a green pixel G. These unit pixels are arranged two-dimensionally and repeatedly in a first direction (an X direction) and a second direction (a Y direction). In other words, in a unit pixel in the form of a 2×2 array, two green pixels G are placed diagonally on one side (e.g., green pixels G1 and G2), and one blue pixel B and one red pixel R are placed diagonally on the other side. When examining the overall pixel arrangement, a first row, in which a plurality of green pixels G and a plurality of blue pixels B are alternately arranged in the first direction, and a second row, in which a plurality of red pixels R and a plurality of green pixels G are alternately arranged in the first direction, are arranged repeatedly in the second direction.

However, the arrangement form of the pixel array 1100 of the image sensor 1000 is not limited to the Bayer pattern, and various arrangement forms other than the Bayer pattern are also possible. For example, in one or more embodiments, the CYGM-type arrangement, in which a magenta pixel M, a cyan pixel C, a yellow pixel Y, and a green pixel G constitute one unit pixel, is also possible. In addition, in one or more embodiments, an RGBW-type arrangement, in which a green pixel G, a red pixel R, a blue pixel B, and a white pixel W constitute one unit pixel, is also possible.

Additionally, pixels of the pixel array 1100 may be arranged in various ways depending on the color characteristics of the image sensor 1000. Hereinafter, for convenience, the pixel array 1100 of the image sensor 1000 is described as having the Bayer pattern. However, the principles of the embodiments described below may be applied to other types of pixel arrays other than the Bayer pattern.

In addition, the pixel array 1100 of the image sensor 1000 according to one or more embodiments may have a tetra-array form, nona-array form, or hexadeca-array form.

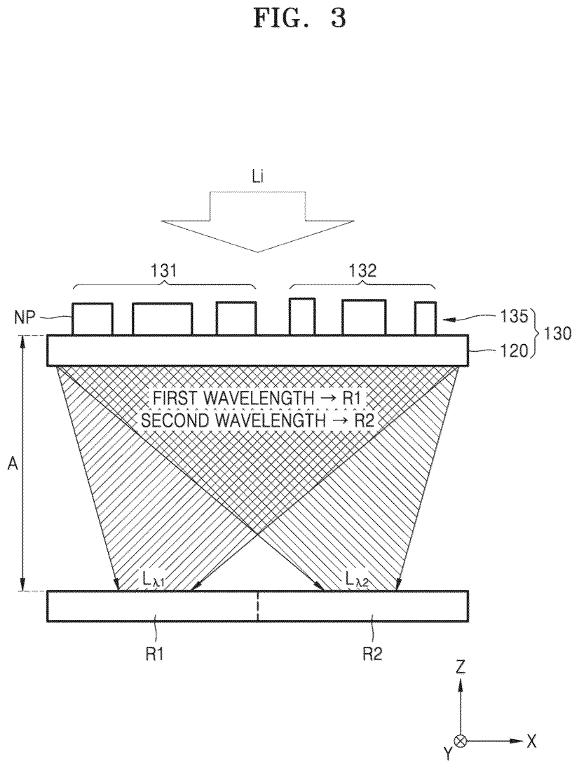

FIG. 3 is a conceptual diagram schematically showing a structure and operation of a color-routing element 130 according to one or more embodiments. According to one or more embodiments, the pixel array 1100 of the image sensor 1000 may include a color-routing element 130 configured to converge light of a corresponding color on each pixel.

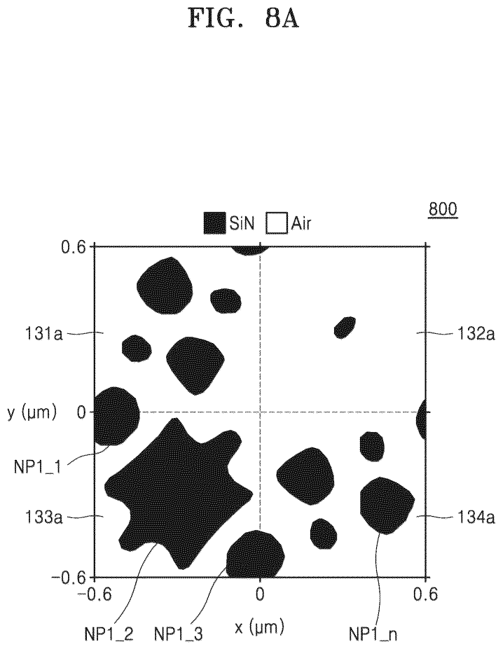

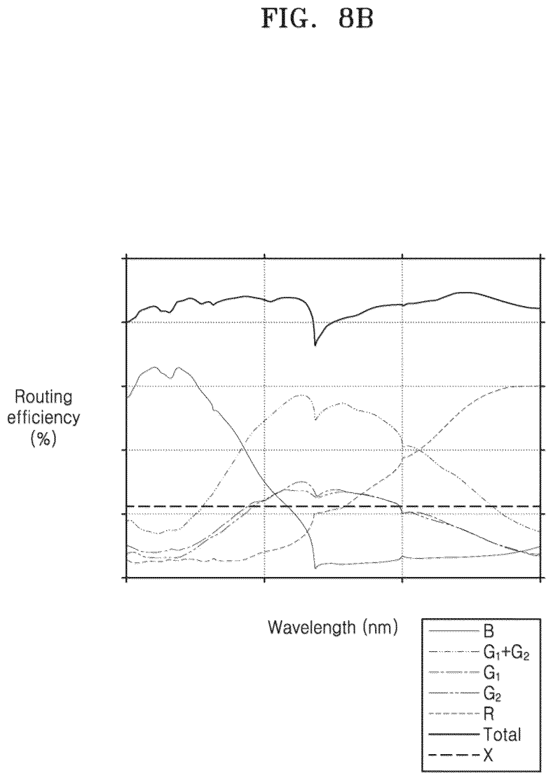

Referring to FIG. 3, the color-routing element 130 according to one or more embodiments may include a nanostructure array 135 in which a target unit pattern is arranged repeatedly. For example, in the nanostructure array 135, a target unit pattern (e.g., 800 in FIG. 8A) may be two-dimensionally and repeatedly arranged in the first direction (the X direction) and the second direction (the Y direction). The nanostructure array 135 may be disposed on a spacer layer 120 (or a support layer).

In one or more embodiments, the target unit pattern may include, as a pattern including a single layer, a plurality of nanostructures NP that are arranged in a freeform on the basis of at least one color-routing figure of merit. The color-routing element 130 including the plurality of nanostructures NP may modulate the characteristics of light and route the light for each of wavelengths to a target pixel on the basis of the shape, size, and arrangement of the plurality of nanostructures NP. Herein, the light passing through the color-routing element 130 is routed to the corresponding pixel for each wavelength, and the color-routing figure of merit may be calculated based on the intensity of light received at the center of the pixel (e.g., the focal position of the pixel). Herein, the plurality of nanostructures NP arranged in a freeform may indicate that there is no regularity or periodicity in the shape, size, spacing, and arrangement of each of the plurality of nanostructures NP. For example, the plurality of nanostructures NP may include a combination of intuitively shaped nanostructures or a combination of non-intuitively shaped nanostructures. The combination of intuitively shaped nanostructures may include nanostructures having regular geometric shapes, such as polygons (e.g., triangles, quadrangles, and rectangles) and circles (e.g., ovals and circles). The combination of non-intuitively shaped nanostructures may include nanostructures having irregular or different geometric shapes (e.g., NP1_1 to NP1_4 in FIG. 8A).

In one or more embodiments, the target unit pattern may include a first region 131 and a second region 132. For example, the first region 131 and the second region 132 may each include one or more nanostructures NP. The first region 131 and the second region 132 may arranged facing a first target region R1 and a second target region R2, respectively, in one-to-one correspondence. The diagram illustrates that three nanostructures NP are arranged in each of the first region 131 and the second region 132, but this is only an example. In addition, the diagram illustrates that the nanostructures NP are arranged entirely inside each of the first region 131 and the second region 132, but the embodiment is not limited thereto. Some nanostructures NP may be arranged at the boundary between the first region 131 and the second region 132.

The nanostructure array 135 of the color-routing element 130 may allow light of two or more different wavelengths (e.g., light of a first wavelength L_{λ1} and light of a second wavelength L_{λ2}) in incident light Li to branch in different directions and focus on different pixels (e.g., the first target region R1 and the second target region R2).

In one or more embodiments, the shape, size, and arrangement of the plurality of nanostructures NP distributed in the first region 131 and the second region 132 may be determined according to color-routing figures of merit at the first target region R1 and the second target region R2. Depending on the shape, size, and arrangement of the plurality of nanostructures NP, the light of the first wavelength L_{λ1} and light of the second wavelength L_{λ2} may be focused on the first and second target regions R1 and R2 at a certain distance A from the nanostructure array 135.

In one or more embodiments, the rule of arranging the plurality of nanostructures NP in the first region 131 may be different from the rule of arranging the plurality of nanostructures NP in the second region 132. In other words, at least one of the shape, size, and arrangement of the nanostructures NP provided in the first region 131 may be different from the shape, size, and arrangement of the nanostructures NP provided in the second region 132.

Each of the nanostructures NP may include, but is not limited to, silicon nitride (SiN) and/or titanium dioxide (TiO₂) and a combination thereof. The nanostructure NP that has a difference in refractive index from a surrounding material may change the characteristics (e.g., a phase) of light passing through the nanostructure NP. The surrounding material may include a dielectric material having a lower refractive index than the nanostructure NP. For example, the surrounding material may include air, but the embodiment is not limited thereto. In addition, the surrounding material may include a protective layer for protecting the nanostructures NP (or the nanostructure array). Herein, the protective layer may include SU-8 material, etc.

The color-routing element 130 is for branching the incident light Li according to wavelengths and focusing the branched light on different first and second target regions R1 and R2. Therefore, the detailed shape and arrangement pattern of the plurality of nanostructures NP are determined according to target unit patterns that are manufactured to achieve such branching and focusing with high efficiency at desired locations. The method of manufacturing the target unit patterns is described below in detail with reference to FIG. 7.

In FIG. 3, a first wavelength λ1 and a second wavelength λ2 may include a visible light wavelength band, but the embodiment is not limited thereto. Various wavelength bands may be formed according to the shape and arrangement of the plurality of nanostructures NP in the target unit pattern. In addition, a case, in which the incident light is branched into two wavelengths and focused, has been illustrated, but the embodiment is not limited thereto. Depending on wavelengths, the incident light may be branched in three or more directions and then focused.

Hereinafter, an example, in which the color-routing element 130 described above is applied to the pixel array 1100 of the image sensor 1000, is described in more detail.

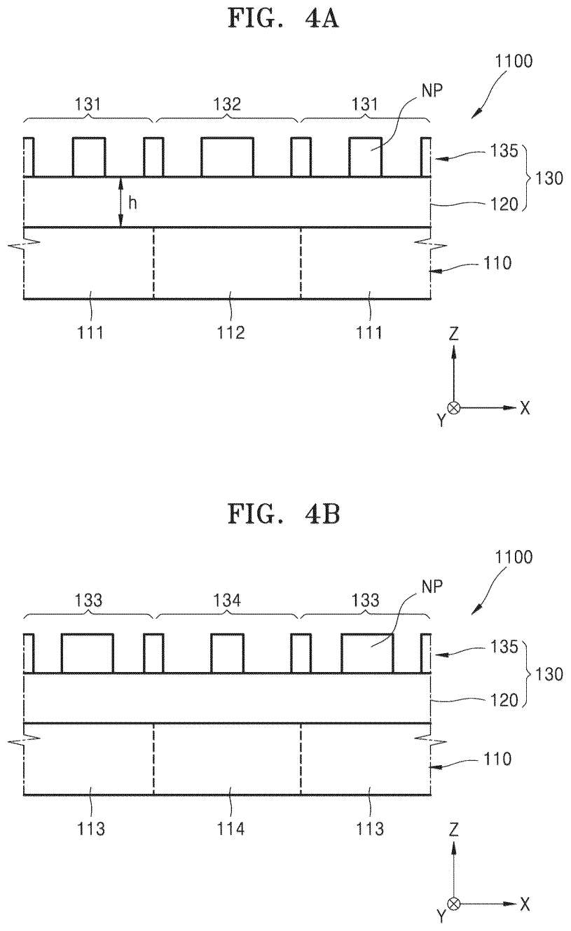

FIGS. 4A and 4B are schematic cross-sectional views showing different cross-sections of a pixel array 1100 in an image sensor according to one or more embodiments.

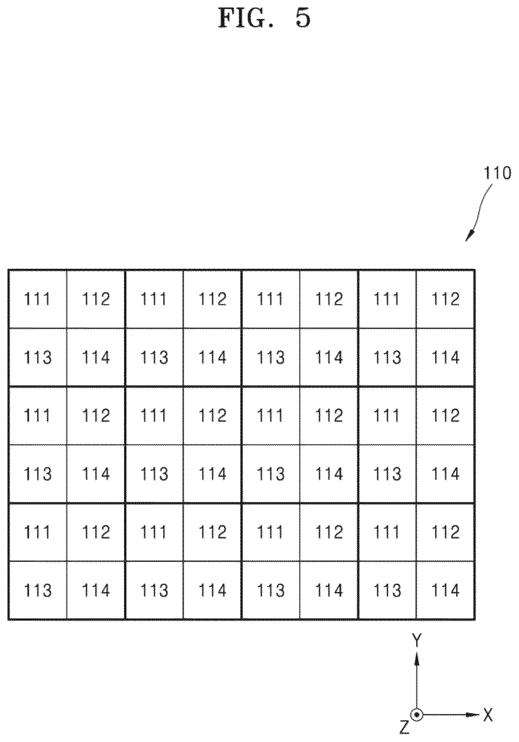

FIG. 5 is a plan view schematically showing arrangement of photo-sensing cells in a pixel array of an image sensor according to one or more embodiments.

Referring to FIGS. 4A and 4B, the pixel array 1100 may include a sensor substrate 110 including a plurality of photo-sensing cells 111, 112, 113, and 114 (or referred to as first to fourth photo-sensing cells 111, 112, 113, and 114) for sensing light, a spacer layer 120 disposed on the sensor substrate 110, and a nanostructure array 135 disposed on the spacer layer 120.

The sensor substrate 110 may include the first photo-sensing cell 111, a second photo-sensing cell 112, a third photo-sensing cell 113, and a fourth photo-sensing cell 114 that convert light into electrical signals. The first photo-sensing cell 111 and the second photo-sensing cell 112 may be alternately arranged in the first direction (X direction) as shown in FIG. 4A. Also, in a cross-section at a different position in the Y direction, the third photo-sensing cell 113 and the fourth photo-sensing cell 114 may be alternately arranged as shown in FIG. 4B. This division of regions is for dividing incident light in units of pixels and sensing the divided incident light. For example, the first photo-sensing cell 111 and the fourth photo-sensing cell 114 may sense light of a first wavelength corresponding to a first pixel, the second photo-sensing cell 112 may sense light of a second wavelength corresponding to a second pixel, and the third photo-sensing cell 113 may sense light of a third wavelength corresponding to a third pixel. Hereinafter, an example is given in which the light of the first wavelength corresponds to green light, the light of the second wavelength corresponds to blue light, and the light of the third wavelength corresponds to red light. In addition, the first pixel, the second pixel, and third pixel correspond to a green pixel G, a blue pixel B, and a red pixel R, respectively. However, the nanostructure array 135 according to one or more embodiments is not limited thereto. A separator may be further formed at the boundary between cells so as to separate the cells.

The spacer layer 120 (or a support layer) may support the color-routing element 130 and maintain a constant distance between the sensor substrate 110 and the color-routing element 130 and may include a material that is transparent to visible light. For example, the spacer layer 120 may include dielectric materials, such as SiO₂ and siloxane-based spin on glass (SOG), which exhibit a lower refractive index than that of the nanostructure NP of the color-routing element 130 and also exhibit a low absorption rate in the visible light band.

The color-routing element 130 includes nanostructures NP arranged in a certain rule. The color-routing element 130 may further include a protective layer for protecting the nanostructures NP. The protective layer may include a dielectric material having a lower refractive index than that of the material forming the nanostructures NP.

In the color-routing element 130, the target unit pattern may have a one-to-one correspondence with one unit pixel (see FIG. 2). For example, the target unit pattern may be divided into first to fourth regions 131, 132, 133, and 134. Also, the first to fourth regions 131, 132, 133, and 134 may face the plurality of first to fourth photo-sensing cells 111, 112, 113, and 114, respectively, in one-to-one correspondence. One or a plurality of nanostructures NPs may be arranged in each of the first to fourth regions 131, 132, 133, and 134, and any one of the shape, size, and arrangement thereof may vary depending on the regions.

The target unit pattern is divided into several regions such that the light of the first wavelength is branched and focused on the first photo-sensing cell 111 and the fourth photo-sensing cell 114, the light of the second wavelength is branched and focused on the second photo-sensing cell 112, and the light of the third wavelength is branched and focused on the third photo-sensing cell 113. Also, the size, shape, and arrangement of nanostructures NP may be determined based on the color-routing figure of merit for each of the regions.

When the pixel array 1100 has the arrangement of Bayer pattern as shown in FIG. 2, the first photo-sensing cell 111 and the fourth photo-sensing cell 114 in FIG. 5 correspond to green pixels G (e.g., G1 and G2), the second photo-sensing cell 112 corresponds to the blue pixel B, and the third photo-sensing cell 113 corresponds to the red pixel R.

The first and fourth regions 131 and 134 of the color-routing element 130 may correspond to the green pixel G, the second photo-sensing cell 112 and the second region 132 may correspond to the blue pixel B, and the third photo-sensing cell 113 and the third region 133 may correspond to the red pixel R. Therefore, the color-routing element 130 may include a plurality of target unit patterns (e.g., repetitively arranged target unit patterns) arranged two-dimensionally, and each of the target unit patterns includes the first region 131, the second region 132, the third region 133, and the fourth region 134 which are arranged in a 2×2 form.

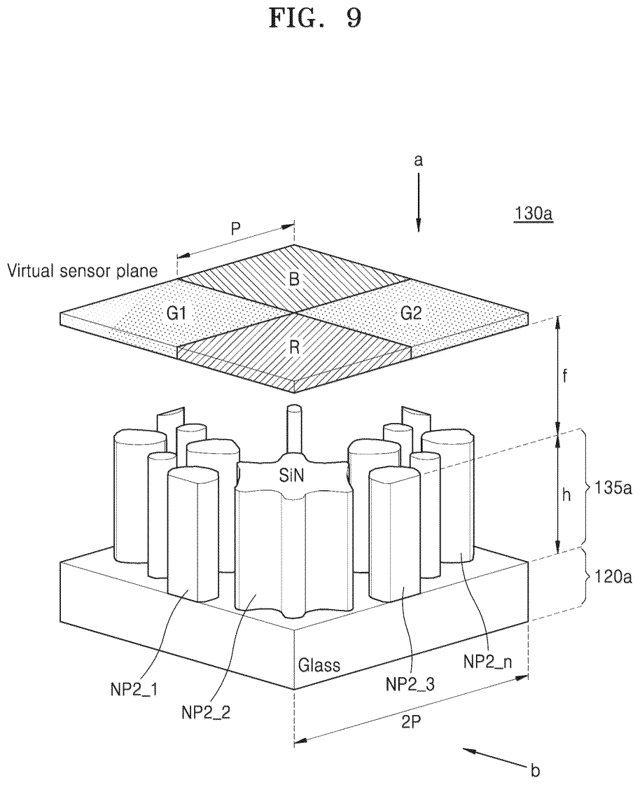

As shown in FIG. 9 below, the first and fourth regions 131 and 134 corresponding to the green pixel G, the second region 132 corresponding to the blue pixel B, the third region 133 corresponding to the red pixel R may include three-dimensional (3D) nanostructures NP having cross-sections of various shapes. For example, the nanostructures NP having different cross-sectional areas may be arranged in a freeform in the first region 131, the second region 132, the third region 133, and the fourth region 134. That is, the shapes may be irregular or different from one another. Additionally or alternatively, spacing and/or arrangement between different nanostructures NP may be irregular or different. In addition, the nanostructures NP may be arranged at the center of boundaries between pixels and at the intersection of boundaries between pixels.

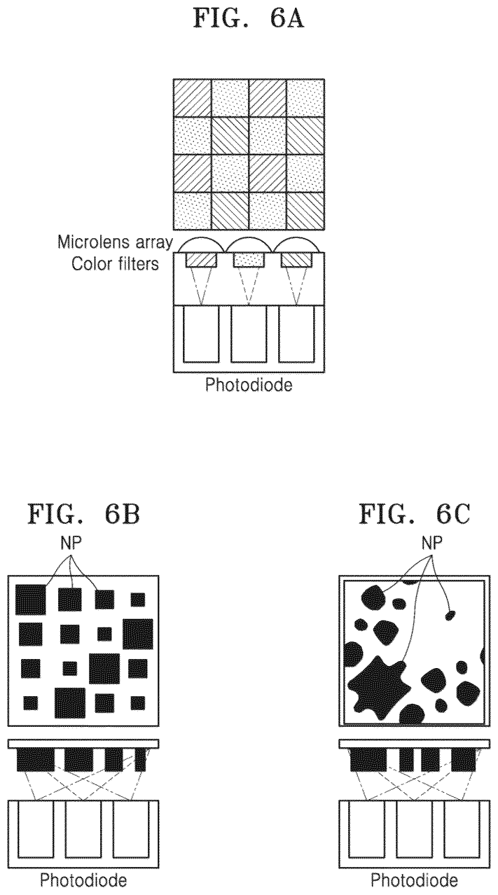

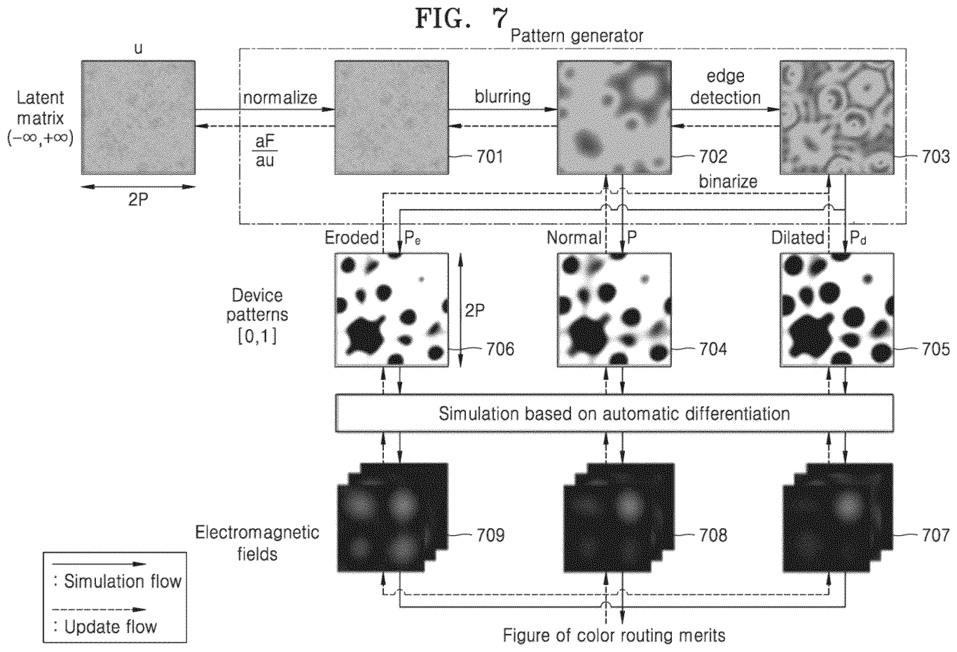

FIGS. 6A-6C are diagrams comparing elements according to comparative examples to a color-routing element according to one or more embodiments.

Referring to FIG. 6A, an image sensor based on a microlens array and a color filter according to a comparative example is shown. The color filter in FIG. 6A absorbs light of all incident light except for the wavelength corresponding to each pixel, and thus, light use efficiency is significantly reduced. Also, since the size of the pixel becomes smaller, there is an issue regarding signal-to-noise ratio (SNR).

Referring to FIG. 6B, a nanostructure array (e.g., a metasurface) including a plurality of nanostructures NP manufactured according to a manufacturing method of a color-routing element according to the comparative example and an image sensor including the nanostructure array are shown. The color-routing element in IG. 6B performs color routing to redistribute light of a predetermined wavelength to a target photodiode via a nanostructure array and may thus overcome the issue of reduced light use efficiency and the issue related to SNR in the color filter in FIG. 6A. However, in the manufacturing method of the color-routing element in FIG. 6B, a color-routing element may be manufactured by understanding the modulation characteristics of light and arranging nanostructures NP to perform the color-routing function at each location. Therefore, in the manufacturing method of the color-routing element in FIG. 6B, the degree of design freedom regarding the arrangement and shape of nanostructures NP is low. Accordingly, the nanostructures NP may be formed only as limited patterns during the manufacturing process. Therefore, the color-routing element in FIG. 6B has limitations in improving color-routing efficiency.

Referring to FIG. 6C, a color-routing element 130 including a plurality of nanostructures NP manufactured by a manufacturing method of the color-routing element 130 according to one or more embodiments and an image sensor including the color-routing element 130 are shown. Unlike FIG. 6B, the manufacturing method of the color-routing element 130 according to the embodiment may calculate the color-routing figure of merit at each pixel (or the focus of each pixel) using an electromagnetic field simulation based on an automatic differentiation technique. Also, the target unit pattern (i.e., the shape and arrangement of the plurality of nanostructures NP within the target unit pattern) of the color-routing element 130 may be manufactured in a way to improve the calculated color-routing figure of merit. Therefore, in the manufacturing method of the color-routing element 130 according to the embodiment, the nanostructures NP may be arranged in freeform in order to maximize the degree of design freedom regarding the shape, size, spacing, and arrangement of nanostructures NP within the target unit pattern during the manufacturing process. Therefore, in the manufacturing method of the color-routing element 130 according to one or more embodiments, the color-routing element 130 that maximizes the color-routing efficiency may be manufactured/generated.

According to the color-routing element 130, the manufacturing method therefor, and the image sensor including the color-routing element 130 according to various embodiments, the color-routing element 130 including the nanostructure array (or the target unit pattern) may be used to separate and focus the incident light for each wavelength without absorbing/blocking the incident light. Therefore, the light use efficiency and color-routing efficiency may be improved.

In addition, in the manufacturing method of the color-routing element 130 according to one or more embodiments, the color-routing element 130 (i.e., the nanostructure array of the color-routing element 130) is manufactured/produced by reflecting possible process errors in the manufacturing process. Accordingly, the color-routing element 130 or the image sensor including the same with robustness to the process errors may be manufactured/produced. The color-routing element 130 and the manufacturing method therefor according to one or more embodiments are described in detail below with reference to FIG. 7.

FIG. 7 is a diagram illustrating a method of manufacturing a color-routing element according to one or more embodiments.

FIG. 7 is a diagram illustrating a method of manufacturing/producing the color-routing element 130 (e.g., the target unit pattern of the color-routing element 130) according to one or more embodiments. The method of manufacturing the color-routing element 130 described in FIG. 7 may be performed by hardware elements and/or software elements (e.g., a topology optimization algorithm).

In FIG. 7, the solid arrow represents a simulation flow diagram so as to calculate the color-routing figure of merit and/or gradient for unit patterns (e.g., a reference unit pattern 704, and first and second comparison unit patterns 705 and 706) generated based on an initial matrix u. Also, the dashed arrow line represents an update flow diagram so as to update the initial matrix u based on simulation results.

Referring to FIG. 7, according to the manufacturing method of the color-routing element 130 according to one or more embodiments, a pattern generator according to one or more embodiments may receive the initial matrix u of size 2P (e.g., P=600 nm) generated from a latent matrix. Here, the initial matrix u may include an initial unit pattern for generating the target unit pattern of the color-routing element 130. The latent matrix may include a matrix related to a reparameterization to latent variables task and a potential noise vector in generative adversarial networks (GANs) and may represent a space without restrictions regarding the range of the matrix and/or the correlation between adjacent points in the matrix. For example, the range of the latent matrix may be (−∞, +∞). The initial matrix u generated from the latent matrix may also include unrestricted values. Herein, the latent matrix may be understood as a set of matrices that are latently generated as an initial unit pattern. For example, the initial matrix u may be the subject of evaluation for the color-routing figure of merit and/or gradient.

In one or more embodiments, the pattern generator may generate a matrix (u1) 701 by normalizing the initial matrix u, in order to minimize errors according to scales in a subsequent process (e.g., gradient-based update, etc.).

In one or more embodiments, the pattern generator may generate a matrix (u2) 702 by performing blurring on the matrix (u1) 701 on the basis of Gaussian kernel. The pattern generator may generate a reference unit pattern (ρ) (normal) 704 by performing binarization on the matrix (u2) 702. Herein, the size of the reference unit pattern (ρ) 704 may be 2P (e.g., P=600 nm), and the range of device parameters may include [0, 1], considering continuous values of device density or permittivity between air and a target material. The reference unit pattern (ρ) 704 may represent an ideal unit pattern that is generated to satisfy the target condition (e.g., the condition of minimum processable line width sizes (about 50 nm)) in a production process (e.g., a lithography process) of the color-routing element 130.

In one or more embodiments, the pattern generator may generate a matrix (u3) 703 by performing edge detection on the matrix (u2) 702 on the basis of edge detection kernel.

The pattern generator may perform binarization on the matrix (u3) 703 to produce at least one comparison unit pattern (e.g., a first comparison unit pattern (ρ_{d}) (Dilated) 705 and/or a second comparison unit pattern (ρₑ) (Eroded) 706). Herein, the size of at least one comparison unit pattern may be 2P (e.g., P=600 nm), and the range of device parameters may include [0, 1], considering continuous values of device density or permittivity between air and a target material. The at least one comparison unit pattern (e.g., the first comparison unit pattern (ρ_{d}) 705 and/or the second comparison unit pattern (ρₑ) 706) may represent at least one unit pattern generated by reflecting process errors that occur during the production process (e.g., a lithography process) of the color-routing element 130.

In one or more embodiments, the pattern generator may generate the first comparison unit pattern (ρ_{d}) 705 by adding a detected edge to each of boundary portions of the reference unit pattern (ρ) 704. That is, the first comparison unit pattern (ρ_{d}) 705 may be generated by dilating the boundary portion of the reference unit pattern (ρ) 704 in the amount of the detected edge. In one or more embodiments, the pattern generator may generate the second comparison unit pattern (ρₑ) 706 by subtracting a detected edge from each of boundary portions of the reference unit pattern (ρ) 704. That is, the second comparison unit pattern (ρₑ) 706 may be generated by eroding the boundary portion of the reference unit pattern (ρ) 704 in the amount of the detected edge.

In one or more embodiments, a simulation device may perform, on the received reference unit pattern (ρ) 704, the first comparison unit pattern (ρ_{d}) 705, and the second comparison unit pattern (ρₑ) 706, electromagnetic field simulation (e.g., 707, 708, and 709 in FIG. 7) based on an automatic differentiation technique. Through the electromagnetic field simulation based on the above automatic differentiation technique, the simulation device may calculate the color-routing figure of merit (e.g., performance of the color-routing element 130) for each of the reference unit pattern (ρ) 704, the first comparison unit pattern (ρ_{d}) 705, and the second comparison unit pattern (ρₑ) 706. The simulation device may calculate the total color-routing figure of merit on the basis of the color-routing figure of merit for each of the reference unit pattern (ρ) 704, the first comparison unit pattern (ρ_{d}) 705, and the second comparison unit pattern (ρₑ) 706 (or simply referred to as the unit patterns 704 to 706). If the total color-routing figure of merit (or the color-routing figure of merit for each of the unit patterns 704 to 706) does not converge, the simulation device may calculate the gradient for the total color-routing figure of merit (or the color-routing figure of merit for each of the unit patterns 704 to 706). Here, the gradient may include information representing a direction for improving the color-routing figure of merit, as information required when updating the initial matrix u. The electromagnetic field simulation based on the automatic differentiation technique may represent calculating the differentiation for a system (e.g., simulation of electromagnetic fields) including a synthesis of various differentiable functions using the computing capability of a computer and the chain rule. Herein, the electromagnetic field simulation based on automatic differentiation technique may include rigid coupled wave analysis (RCWA) simulation or finite-difference time-domain (FDTD) simulation. Also, this method may calculate the gradient by performing a minimum number of simulations compared to the existing adjoint variable method or perturbation.

In one or more embodiments, the simulation device may calculate the color-routing figure of merit (F(ρ)) for the reference unit pattern (ρ) 704, the first comparison unit pattern (ρ_{d}) 705, and the second comparison unit pattern (ρₑ) 706, on the basis of Equation 1, through the electromagnetic field simulation based on automatic differentiation technique.

$$F ( ρ ) = {\sum }_{λ} {log}_{10} [ {\int }_{{A}_{λ}} Re ( {S}_{z} ( ρ ) ) dxdy ] \qquad [ Equation 1 ]$$

Herein, light is routed to a target region (A_{λ}) (e.g., a region having a side length of 400 nm) of a pixel corresponding to each wavelength by using each unit pattern (e.g., the reference unit pattern (ρ) 704, the first comparison unit pattern (ρ_{d}) 705, the second comparison unit pattern (ρₑ) 706)) and then received by the target region (A_{λ}) of the pixel. Herein, ∫_{Aλ}Re(S_{z}(ρ))dxdy may represent the intensity of light described above. For example, as the intensity of light received in the target region (A_{λ}) of the pixel increases, the color-routing figure of merit (F(ρ)) may increase.

However, ∫_{Aλ}Re(S_{z}(ρ))dxdy is not limited thereto and may include various mathematical equations that may evaluate the color-routing figure of merit for each of the unit patterns 704 to 706.

In one or more embodiments, the simulation device may calculate the total color-routing figure of merit (Fₜₒₜₐₗ) for the initial matrix u, on the basis of Equation 2, through the electromagnetic field simulation based on the automatic differentiation technique.

$${F}_{total} = {a}_{c} F ( {ρ}_{e} ) + {a}_{n} F ( ρ ) + {a}_{d} F ( {ρ}_{d} ) \qquad [ Equation 2 ]$$

Herein, F(ρ) may represent the color-routing figure of merit for the reference unit pattern (ρ) 704, F(ρ_{d}) may represent the color-routing figure of merit for the first comparison unit pattern (ρ_{d}) 705, and F(ρₑ) may represent the color-routing figure of merit for the second comparison unit pattern (ρₑ) 706. Also, aₑ, aₙ, a_{d} may represent predetermined constants (e.g., aₑ=0.25, aₙ=0.5, a_{d}=0.25).

In one or more embodiments, the simulation device may calculate the color-routing figure of merit for the refractive index error and deposition thickness error of the deposition material which occur in the film deposition process during the production process of the color-routing element 130 through the electromagnetic field simulation based on automatic differentiation technique, and may then calculate the gradient on the basis of the calculation result of the color-routing figure of merit for the refractive index error and the deposition thickness error.

In one or more embodiments, the simulation device may calculate the gradient (i.e., the gradient of the initial matrix (or initial unit matrix) u) by performing the electromagnetic field simulation based on the automatic differentiation technique for the calculated color-routing figure of merit.

In one or more embodiments, the pattern generator may update the initial matrix u in a way to improve the calculated color-routing figure of merit on the basis of the gradient

$$( e . g . \frac{\partial F}{\partial u} )$$

calculated by the electromagnetic field simulation based on the automatic differentiation technique. The target unit pattern (e.g., 800 in FIG. 8A) of the color-routing element 130 may be generated by finally updating the initial matrix u (or the initial unit pattern) using the gradient.

In the manufacturing method of the color-routing element 130 according to one or more embodiments, the target unit pattern may be manufactured by reflecting, to the initial matrix u, not only the characteristics of the ideal target unit pattern (e.g., the reference unit pattern (ρ) 704) but also various process errors that occur during the production process of the color-routing element 130 (e.g., the dilated error and eroded error in the lithography process, the deposition rate error and deposition thickness error in the film deposition process, etc.). Accordingly, it is possible to prevent performance degradation of the color-routing element 130 caused by the process errors.

Accordingly, the color-routing element 130 (or the image sensor based on the color-routing element 130) manufactured/produced by the manufacturing method (FIG. 7) according to one or more embodiments may exhibit not only higher light use efficiency and/or color-routing efficiency than a general color filter (or an image sensor based on the color filter), but also show high robustness to process errors.

FIG. 8A shows an example of a target unit pattern 800 in a color-routing element according to one or more embodiments.

In detail, FIG. 8A shows an example of the target unit pattern 800 of the color-routing element 130 that is manufactured/produced using the manufacturing method of the color-routing element 130 of FIG. 7.

Referring to FIG. 8A, the target unit pattern 800 according to one or more embodiments may include a plurality of nanostructures, and the plurality of nanostructures may include a first nanostructure NP1_1, a second nanostructure NP1_2, a third nanostructure NP1_3, . . . , and an nth nanostructure NP1_n. For example, the plurality of nanostructures (e.g., the first nanostructure NP1_1 to the nth nanostructure NP1_n) of the target unit pattern 800 may include silicon nitride (SiN) (or titanium dioxide (TiO₂)). The nanostructure NP that has a difference in refractive index from a surrounding material may change the characteristics (e.g., a phase) of light passing through the nanostructure NP. The surrounding material may include a dielectric material having a lower refractive index than the nanostructure NP. For example, the surrounding material may include air, but the embodiment is not limited thereto. In addition, the surrounding material may include a protective layer for protecting the nanostructures NP (or the nanostructure array). Herein, the protective layer may include SU-8 material, etc.

Referring to FIGS. 4A to 4B and FIG. 8, the target unit pattern 800 may include a first region 131a to a fourth region 134a.

The rules for arranging the plurality of nanostructures in the first region 131a to the fourth region 134a may be different from each other. That is, a plurality of nanostructures provided in the first region 131a to the fourth region 134a may be arranged in a freeform. For example, at least one of the shape, size, spacing, and arrangement of the nanostructures provided in the first region 131a may be different from the shape, size, spacing, and arrangement of the nanostructures provided in the second region 132a to the fourth region 134a. For example, at least one of the shape, size, spacing, and arrangement of the nanostructures provided in the second region 132a may be different from the shape, size, spacing, and arrangement of the nanostructures provided in the first region 131a, the third region 133a, and the fourth region 134a. For example, at least one of the shape, size, spacing, and arrangement of the nanostructures provided in the third region 133a may be different from the shape, size, spacing, and arrangement of the nanostructures provided in the first region 131a, the second region 132a, and the fourth region 134a. For example, at least one of the shape, size, spacing, and arrangement of the nanostructures provided in the fourth region 134a may be different from the shape, size, spacing, and arrangement of the nanostructures provided in the first region 131a, the second region 132a, and the third region 133a.

The plurality of nanostructures (e.g., the first nanostructure NP1_1 to the nth nanostructure NP1_n) in the target unit pattern 800 according to one or more embodiments may include a combination of non-intuitively shaped nanostructures. For example, the non-intuitively shaped nanostructures may represent nanostructures having irregular or different geometric shapes (e.g., refer to the first nanostructure NP1_1 to the nth nanostructure NP1_n in FIG. 8A).

Referring to FIGS. 5 and 8A, the target unit pattern 800 may have a one-to-one correspondence with one unit pixel (see FIG. 2). For example, the target unit pattern 800 may be divided into the first region 131a to the fourth region 134a. Also, the first region 131a to the fourth region 134a may face the plurality of first to fourth photo-sensing cells 111, 112, 113, and 114, respectively, in one-to-one correspondence. For example, when the pixel array 1100 has the arrangement of Bayer pattern as shown in FIG. 2, the first photo-sensing cell 111 and the fourth photo-sensing cell 114 in FIG. 5 correspond to green pixels G (e.g., G1 and G2), the second photo-sensing cell 112 corresponds to the blue pixel B, and the third photo-sensing cell 113 corresponds to the red pixel R. Herein, the first and fourth regions 131a and 134a of the target unit pattern 800 may correspond to the green pixels G1 and G2, the second photo-sensing cell 112 and the second region 132a may correspond to the blue pixel B, and the third photo-sensing cell 113 and the third region 133a may correspond to the red pixel R.

FIG. 8A shows an example of the target unit pattern 800 for convenience of description, but the embodiment is not limited thereto. The color-routing element 130 according to one or more embodiments may include other types of target unit patterns depending on the shape, size, spacing, and arrangement of nanostructures.

FIG. 8B is a graph showing a color-routing efficiency on the basis of the target unit pattern 800 of FIG. 8A.

In detail, FIG. 8B is a graph showing the color-routing efficiency for each wavelength, which is a simulation result of a color-routing operation based on the target unit pattern 800 of FIG. 8A. In FIG. 8B, the horizontal axis may represent the wavelength (nm) (e.g., about 400 nm to about 700 nm) and the vertical axis may represent the color-routing efficiency (%) (e.g., about 0% to about 400%).

Referring to FIG. 8B, it can be seen that the color-routing efficiency of the color-routing element 130 based on the target unit pattern 800 is up to about 240% in regions of the blue light B, green light G1+G2, and red light R. Assuming that the transmission efficiency of the color filter is 90%, the color-routing efficiency of a general color filter-based image sensor may be up to about 90% (‘X’ in FIG. 8B). For example, the color-routing efficiency in the region of blue light B may be up to 260%, the color-routing efficiency in the region of green light G1+G2 may be up to 228%, and the color-routing efficiency in the region of red light R may be up to 240%. It can be seen that the color-routing efficiency of the image sensor based on the color-routing element 130 according to one or more embodiments is greater than that of the image sensor based on the color filter.

When examining the total value in the graph of FIG. 8B, it can be seen that the color-routing element 130 uses up to 356% of the energy of incident visible light band (that is, the light use efficiency of the color-routing element 130 may be up to 356%).

Therefore, the embodiment may provide the color-routing element 130 (or the image sensor based on the color-routing element 130) that exhibits the color-routing efficiency and light use efficiency greater than those of the image sensor based on the color filter.

Furthermore, the color-routing element 130 (or the image sensor based on the color-routing element 130) manufactured according to one or more embodiments may be manufactured by reflecting various process errors that occur during the production process. Therefore, the impact of process errors on device performance may be minimized. For example, the image sensor based on the color-routing element 130 according to one or more embodiments may maintain the performance of elements even if the error range of the actually formed pattern changes to ±10% (or about 5 nm to about 100 nm).

FIG. 9 shows an example of a color-routing element 130a including a target unit pattern according to one or more embodiments.

In detail, FIG. 9 shows an example of the color-routing element 130 produced by forming the target unit pattern 800 of FIG. 8A in a three-dimensional form. When describing FIG. 9, repeated descriptions as those given with reference to FIGS. 8A to 8B are replaced with the descriptions above with reference to FIGS. 8A to 8B.

Referring to FIG. 9, the light (e.g., visible light) incident on the color-routing element 130a according to the embodiment may be divided for each wavelength in a virtual sensor plane based on the Bayer pattern and routed to pixels of colors corresponding to respective wavelengths (e.g., the green pixels G1 and G2, the blue pixel B, and the red pixel R).

The color-routing element 130a may include a spacer layer 120a (e.g., glass substrate) and a nanostructure array 135a deposited, as a silicon nitride (SiN) layer with a predetermined thickness h (e.g., about 600 nm), on the spacer layer 120a. The nanostructure array 135a may include a plurality of 3D nanostructures (e.g., a first nanostructure NP2_1 to an nth nanostructure NP2_n) provided as a single layer. The plurality of nanostructures in FIG. 9 (e.g., the first nanostructure NP2_1 to the nth nanostructure NP2_n) may have a structure formed by representing the plurality of nanostructures (e.g., the first nanostructure NP1_1 to the nth nanostructure NP1_n) of FIG. 8A in a 3D form. For example, a focal length f, which is the distance between the nanostructure array 135a and the virtual sensor plane, may be set to 600 nm, and the size of the pixels in the virtual sensor plane may be set to P (P=600 nm). Also, the repetition period of the target unit pattern 800 in the nanostructure array 135a may be set to 2P (P=600 nm). However, the settings for the configuration of the color-routing element 130 described above are examples for convenience of description. Also, the configuration of the color-routing element 130 according to one or more embodiments may be set to other values.

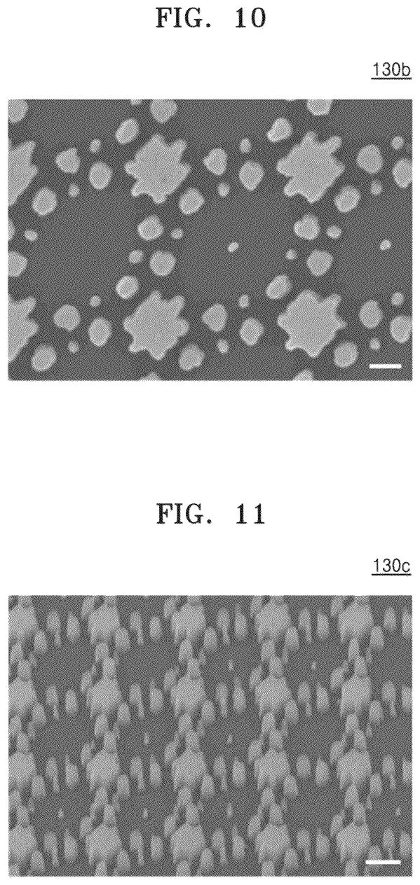

FIG. 10 shows an example of a color-routing element according to one or more embodiments. In detail, FIG. 10 shows an image of the color-routing element 130b in which the target unit pattern manufactured by the manufacturing method of the color-routing element 130 according to one or more embodiments (see FIG. 7) is repeatedly arranged, wherein the image described above is captured in the direction a of FIG. 9 (e.g., a scanning electron microscope (SEM) image).

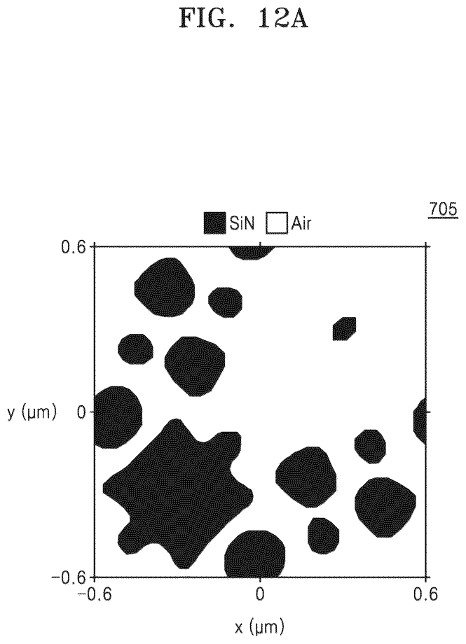

FIG. 11 shows an example of a color-routing element 130b according to one or more embodiments. In detail, FIG. 11 shows an image of the color-routing element 130c in which the target unit pattern manufactured by the manufacturing method of the color-routing element 130 according to one or more embodiments (see FIG. 7) is repeatedly arranged, wherein the image described above is captured in the direction b (tilted) of FIG. 9 (e.g., an SEM image).

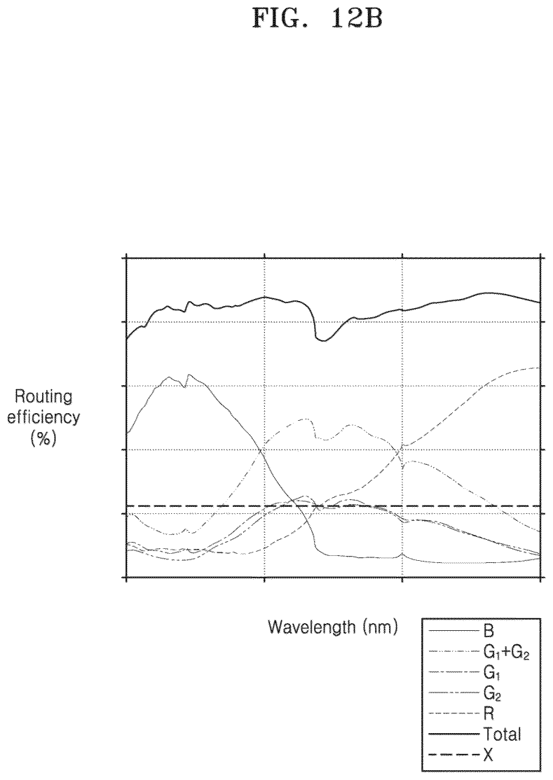

FIG. 12A shows an example of a comparison unit pattern according to one or more embodiments.

In detail, FIG. 12A shows an example of a first comparison unit pattern (ρ_{d}) 705 generated by reflecting a process error (e.g., a dilated error) occurring in a lithography process. Herein, the range of process error (e.g., the dilated error) may be from about 5 nm to about 100 nm depending on equipment, but the embodiment is not limited thereto. When describing FIG. 12A, repeated descriptions as those given with reference to FIG. 7 are replaced with the descriptions above with reference to FIG. 7.

Referring to FIGS. 7 and 12A, the first comparison unit pattern (ρ_{d}) 705 may be generated by adding a detected edge to each of boundary portions of the reference unit pattern (ρ) 704. That is, the first comparison unit pattern (ρ_{d}) 705 may be generated by dilating the boundary portion of the reference unit pattern (ρ) 704 in the amount of the detected edge.

FIG. 12B is a graph showing a color-routing efficiency on the basis of the comparison unit pattern of FIG. 12A.

Specifically, FIG. 12B is a graph showing the color-routing efficiency for each wavelength, which is the simulation result of the color-routing operation based on the first comparison unit pattern (ρ_{d}) 705 of FIG. 12A. In FIG. 12B, the horizontal axis may represent the wavelength (nm) (e.g., about 400 nm to about 700 nm) and the vertical axis may represent the color-routing efficiency (%) (e.g., about 0% to about 400%).

Referring to FIG. 12B, it can be seen that the color-routing efficiency is up to about 240% in regions of blue light B, green light G1+G2, and red light R. Assuming that the transmission efficiency of the color filter is 90%, the color-routing efficiency of a general color filter-based image sensor may be up to about 90% (‘X’ in FIG. 12B). It can be seen that the color-routing efficiency of the color-routing element 130 based on the first comparison unit pattern (ρ_{d}) 705 according to one or more embodiments is higher than that of the color filter-based image sensor.

Therefore, according to one or more embodiments, despite process errors (e.g., dilated errors) in the lithography process, it is possible to provide the color-routing element 130 (or the image sensor based on the color-routing element 130) exhibiting the higher color-routing efficiency than the image sensor based on the color filter.

Furthermore, the image sensor based on the color-routing element 130 manufactured according to one or more embodiments is manufactured to reflect process errors (e.g., dilated errors) in the lithography process, and thus, the impact of the process errors on device performance may be minimized.

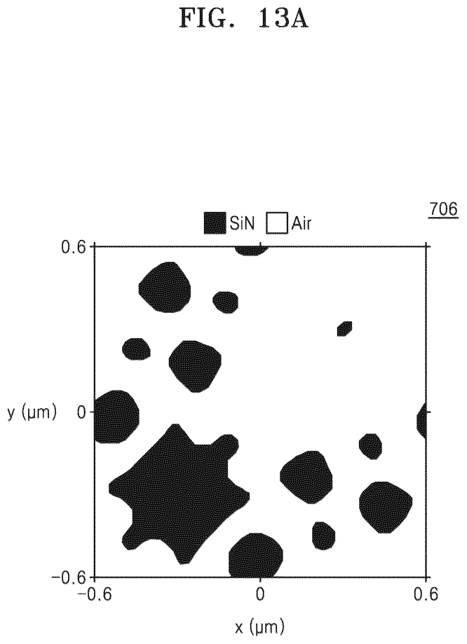

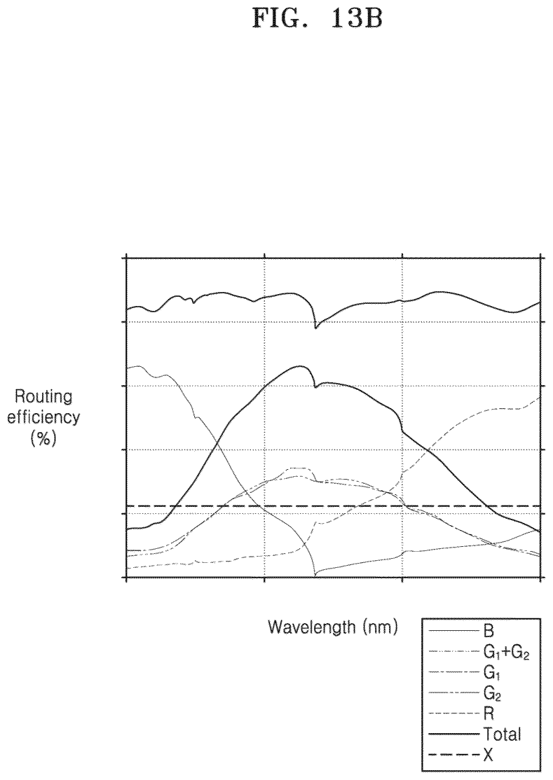

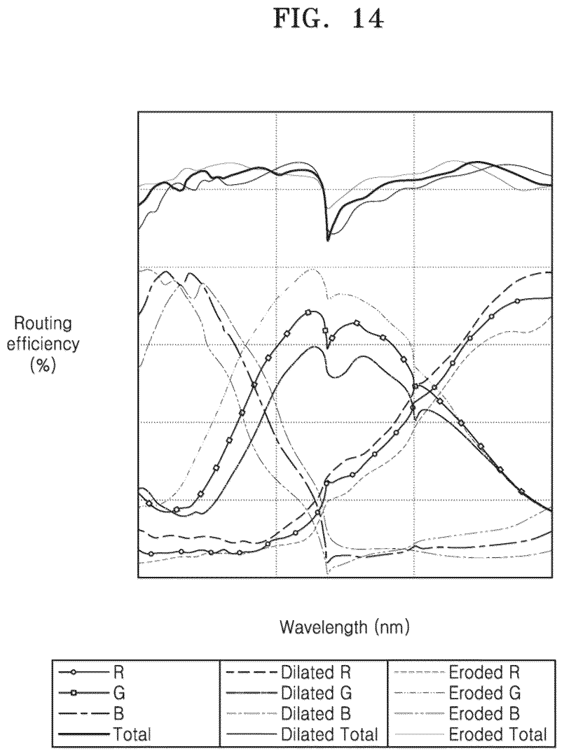

FIG. 13A shows another example of a comparison unit pattern according to one or more embodiments.

In detail, FIG. 13A shows an example of a second comparison unit pattern (ρₑ) 706 generated by reflecting a process error (e.g., an eroded error) occurring in a lithography process. Herein, the range of process error (e.g., the eroded error) may be from about 5 nm to about 100 nm depending on equipment, but the embodiment is not limited thereto. When describing FIG. 13A, repeated descriptions as those given with reference to FIG. 7 are replaced with the descriptions above with reference to FIG. 7.

Referring to FIGS. 7 and 13A, the second comparison unit pattern (ρₑ) 706 may be generated by subtracting a detected edge from each of boundary portions of the reference unit pattern (ρ) 704. That is, the second comparison unit pattern (ρₑ) 706 may be generated by eroding the boundary portion of the reference unit pattern (ρ) 704 in the amount of the detected edge.

FIG. 13B is a graph showing a color-routing efficiency on the basis of the comparison unit pattern of FIG. 13A.

Specifically, FIG. 13B is a graph showing the color-routing efficiency for each wavelength, which is the simulation result of the color-routing operation based on the second comparison unit pattern (ρₑ) 706 of FIG. 13A. In FIG. 13B, the horizontal axis may represent the wavelength (nm) (e.g., about 400 nm to about 700 nm) and the vertical axis may represent the color-routing efficiency (%) (e.g., about 0% to about 400%).

Referring to FIG. 13B, it can be seen that the color-routing efficiency is up to about 240% in regions of blue light B, green light G1+G2, and red light R. Assuming that the transmission efficiency of the color filter is 90%, the color-routing efficiency of a general color filter-based image sensor may be up to about 90% (‘X’ in FIG. 13B). It can be seen that the color-routing efficiency of the color-routing element 130 based on the second comparison unit pattern (ρₑ) 706 according to one or more embodiments is higher than that of the color filter-based image sensor.

Therefore, according to one or more embodiments, despite process errors (e.g., eroded errors) in the lithography process, it is possible to provide the color-routing element 130 (or the image sensor based on the color-routing element 130) exhibiting the higher color-routing efficiency than the image sensor based on the color filter.

Furthermore, the image sensor based on the color-routing element 130 manufactured according to one or more embodiments is manufactured to reflect process errors (e.g., eroded errors) in the lithography process, and thus, the impact of the process errors on device performance may be minimized.

FIG. 14 shows a graph comparing color-routing efficiency between a reference unit pattern and a comparison unit pattern according to one or more embodiments.

Specifically, FIG. 14 is a graph comparing the color-routing efficiency of the color-routing element 130 on the basis of each of the reference unit pattern (ρ) 704, the first comparison unit pattern (ρ_{d}) 705, and the second comparison unit pattern (ρₑ) 706. The graph may be generated by simulating the color-routing operation on the basis of each of unit patterns. When describing FIG. 14, repeated descriptions as those given with reference to FIGS. 8B, 12B, and 13 are replaced with the descriptions above with reference to FIGS. 8B, 12B, and 13. In FIG. 14, the horizontal axis may represent the wavelength (nm) (e.g., about 400 nm to about 700 nm) and the vertical axis may represent the color-routing efficiency (%) (e.g., about 0% to about 400%).

In FIG. 14, “R” may represent the color-routing efficiency in the red light region of the color-routing element 130 based on the reference unit pattern (ρ) 704, “G” may represent the color-routing efficiency in the green light region of the color-routing element 130 based on the reference unit pattern (ρ) 704, and “B” may represent the color-routing efficiency in the blue light region of the color-routing element 130 based on the reference unit pattern (ρ) 704. In addition, “Dilated R” may represent the color-routing efficiency in the red light region of the color-routing element 130 based on the first comparison unit pattern (ρ_{d}) 705, “Dilated G” may represent the color-routing efficiency in the green light region of the color-routing element 130 based on the first comparison unit pattern (ρ_{d}) 705, and “Dilated B” may represent the color-routing efficiency in the blue light region of the color-routing element 130 based on the first comparison unit pattern (ρ_{d}) 705. “Eroded R” may represent the color-routing efficiency in the red light region of the color-routing element 130 based on the second comparison unit pattern (ρₑ) 706, “Eroded G” may represent the color-routing efficiency in the green light region of the color-routing element 130 based on the second comparison unit pattern (ρₑ) 706, and “Eroded B” may represent the color-routing efficiency in the blue light region of the color-routing element 130 based on the second comparison unit pattern (ρₑ) 706.

Referring to FIG. 14, as a result of performing the simulation using the color-routing element 130 based on each of the reference unit pattern (ρ) 704, the first comparison unit pattern (ρ_{d}) 705, and the second comparison unit pattern (ρₑ) 706, it can be seen that the color-routing efficiencies of the color-routing element 130 based on each of the reference unit pattern (ρ) 704, the first comparison unit pattern (ρ_{d}) 705, and the second comparison unit pattern (ρₑ) 706 have similar values in the blue light region, green light region, and red light region. It can be seen that the color-routing efficiency of the color-routing element 130 based on each unit pattern is higher than the color-routing efficiency of the color filter (up to about 90%).

Also, as a result of performing the simulation using the color-routing element 130 based on each of the reference unit pattern (ρ) 704, the first comparison unit pattern (ρ_{d}) 705, and the second comparison unit pattern (ρₑ) 706, it can be seen that the light use efficiency of the color-routing element 130 based on each unit pattern (e.g., Total, Dilated Total, Eroded Total in FIG. 14) is higher than the light use efficiency of the color filter (e.g., about 33.3%).

Therefore, the color-routing element 130 (or the image sensor based on the color-routing element 130) manufactured according to one or more embodiments is manufactured to reflect various process errors in the production process and may thus exhibit superior color-routing efficiency than the color filter-based image sensor.

The color-routing element 130 (or the image sensor based on the color-routing element 130) manufactured according to one or more embodiments has high light use efficiency and may thus exhibit excellent SNR performance.

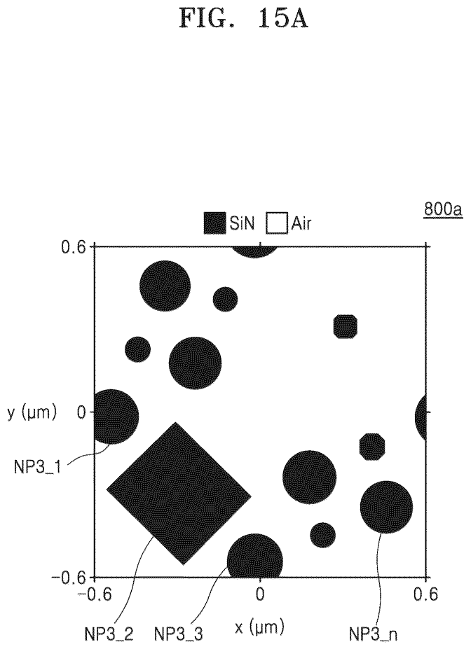

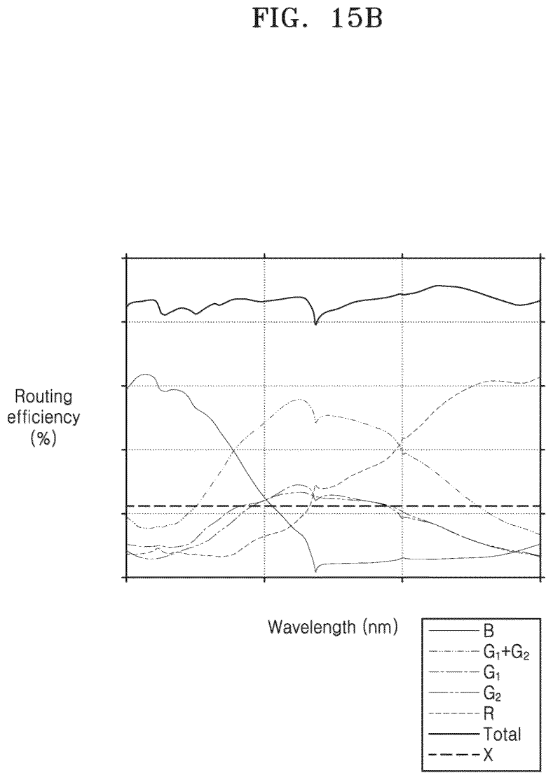

FIG. 15A shows another example of a target unit pattern according to one or more embodiments.

Particularly, FIG. 15A shows another example of a target unit pattern 800a including a plurality of nanostructures (e.g., a first nanostructure NP3_1 to an nth nanostructure NP3_n) which are generated by simplifying (or standardizing) the shapes of the plurality of nanostructures (e.g., the first nanostructure NP1_1 to the nth nanostructure NP1_n) in the target unit pattern 800 of FIG. 8A. When describing FIG. 15A, repeated descriptions as those given with reference to FIG. 8A are replaced with the descriptions above with reference to FIG. 8A.

Referring to FIG. 15A, the plurality of nanostructures (e.g., the first nanostructure NP3_1 to the nth nanostructure NP3_n) in the target unit pattern 800a according to one or more embodiments may include a combination of intuitively shaped nanostructures. For example, the intuitively shaped nanostructures may represent nanostructures having regular geometric shapes, such as polygons and circles. The plurality of nanostructures (e.g., the first nanostructure NP3_1 to the nth nanostructure NP3_n) in the target unit pattern 800a may be arranged in a freeform.

FIG. 15B is a graph showing a color-routing efficiency on the basis of the target unit pattern of FIG. 15A.

In detail, FIG. 15B is a graph showing the color-routing efficiency for each wavelength, which is a simulation result of a color-routing operation based on the target unit pattern 800a of FIG. 15A. When describing FIG. 15B, repeated descriptions as those given with reference to FIG. 8B are replaced with the descriptions above with reference to FIG. 8B. In FIG. 15B, the horizontal axis may represent the wavelength (nm) (e.g., about 400 nm to about 700 nm) and the vertical axis may represent the color-routing efficiency (%) (e.g., about 0% to about 400%).

Referring to FIG. 15B, it can be seen that the color-routing efficiency of the color-routing element 130 based on the target unit pattern 800 is up to about 240% in regions of the blue light B, green light G1+G2, and red light R. It can be seen that the color-routing efficiency of the color-routing element 130 based on the target unit pattern 800a according to one or more embodiments is relatively high, compared to a general color filter-based image sensor having the color-routing efficiency of up to about 90% (‘X’ in FIG. 15B).

Therefore, in the target unit pattern 800a manufactured by the manufacturing method of the color-routing element 130 according to the disclosure, it can be seen that high color-routing efficiency is maintained even when the shapes of the plurality of nanostructures in the target unit pattern 800a are simplified (or standardized).

The embodiment may provide the color-routing element 130 (or the image sensor including the same) having superior color-routing efficiency and robustness to process errors than the color filter-based image sensor.

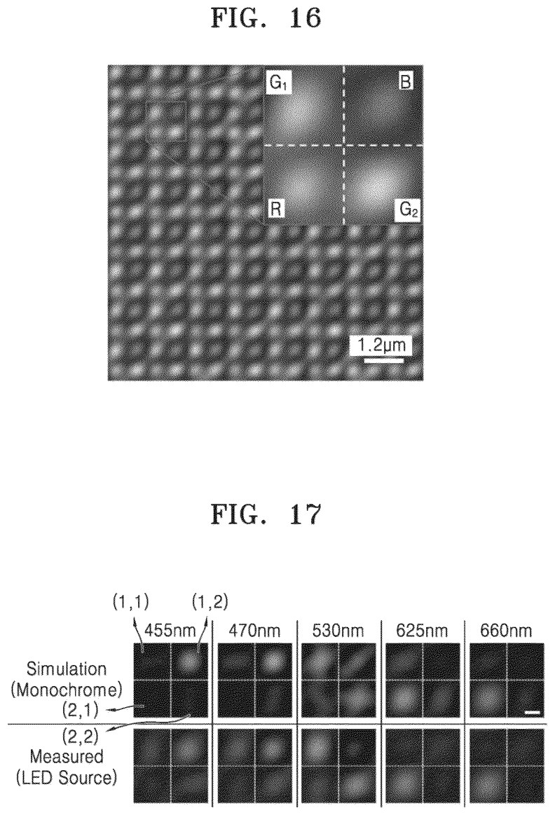

FIG. 16 is a diagram illustrating a color-routing function of a color-routing element according to one or more embodiments.

Referring to FIG. 16, FIG. 16 shows the result of capturing an image of a focal plane (capturing the image with a CCD camera) in the color-routing element 130 according to one or more embodiments using a white light emitting diode (LED). Herein, the size of the focal plane (including the R region, G1 region, B region, and G2 region) corresponding to one target unit pattern is 1.2 m, but the embodiment is not limited thereto.

In FIG. 16, it can be seen that the red light, green light, and blue light are separated and each of the red light, green light, and blue light is focused on the target location. Accordingly, it can be seen that the color-routing element 130 manufactured according to the embodiment may efficiently perform the color-routing function.

FIG. 17 is a diagram illustrating a comparison result of a color-routing function according to one or more embodiments.

Specifically, FIG. 17 is a diagram comparing the results of simulating the color-routing function of the color-routing element 130 according to one or more embodiments with the results of actually measuring the color-routing function. In FIG. 17, the focal plane (where the focal length may be about +0.6 m) has quadrants in the form of a 2×2 matrix, and the location of each quadrant may be displayed through coordinates.

Referring to FIG. 17, as a result of simulating the color-routing function of the color-routing element 130 using a monochrome light source, it can be seen that light (e.g., blue light) in a first wavelength region (455 nm) and a second wavelength region (470 nm) is focused on the (1, 2) position of the focal plane (e.g., the target position of blue light). Also, it can be seen that light (e.g., green light) in a third wavelength region (530 nm) is focused on the (1, 1) and (2, 2) positions of the focal plane (e.g., the target position of green light), and light (e.g., red light) in a fourth wavelength region (625 nm) and a fifth wavelength region (660 nm) is focused on the (2, 1) position of the focal plane (e.g., the target position of red light).

As a result of actually measuring the color-routing function of the color-routing element 130 using an LED light source for each color, it can be seen that the light (e.g., blue light) in the first wavelength region (455 nm) and the second wavelength region (470 nm) is focused on the (1, 2) position of the focal plane (e.g., the target position of blue light). Also, it can be seen that the light (e.g., green light) in the third wavelength region (530 nm) is focused on the (1, 1) and (2, 2) positions of the focal plane (e.g., the target position of green light), and the light (e.g., red light) in the fourth wavelength region (625 nm) and the fifth wavelength region (660 nm) is focused on the (2, 1) position of the focal plane (e.g., the target position of red light).

Therefore, with respect to the color-routing function of the color-routing element 130 according to one or more embodiments, it can be seen that the results of simulating the color-routing function using the monochrome are almost identical to the results of actually measuring the color-routing function using the LED light source for each color.

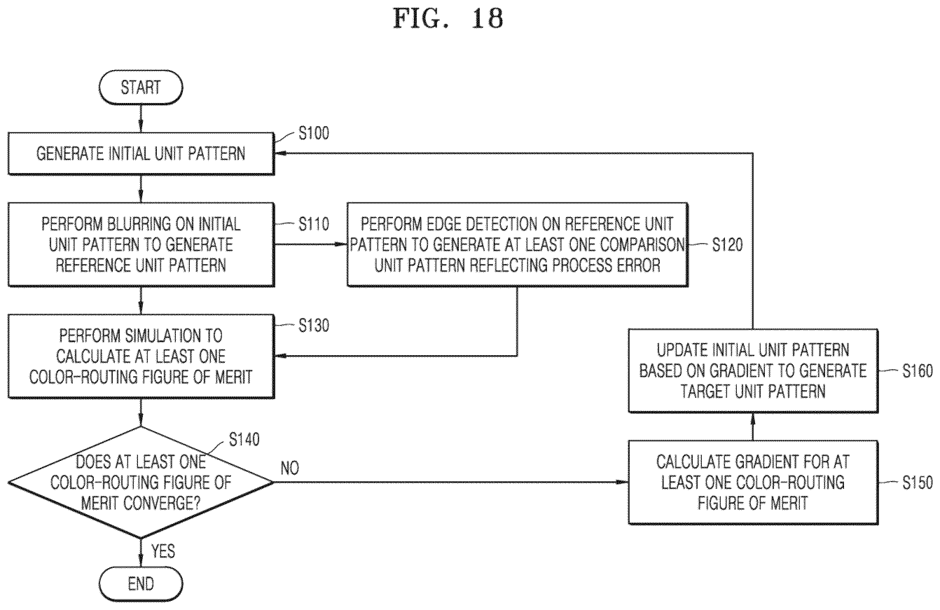

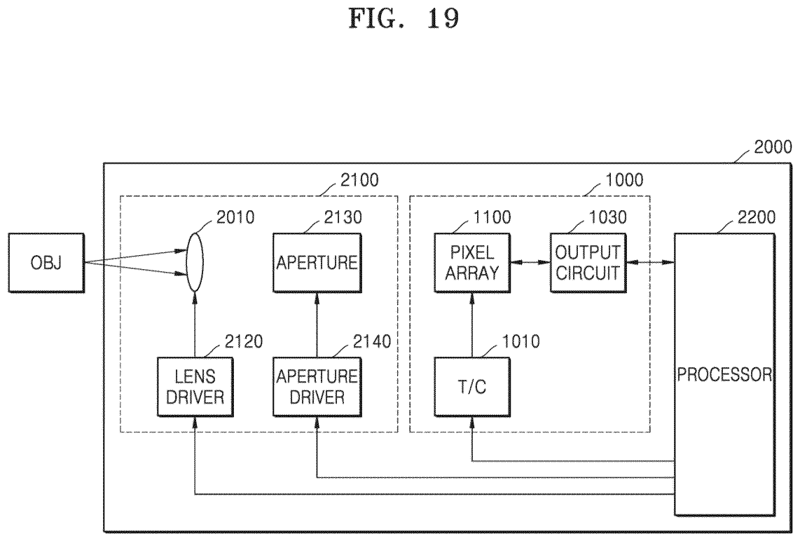

FIG. 18 is a flowchart showing a method of manufacturing a color-routing element, according to one or more embodiments.

Referring to FIG. 18, the manufacturing method of the color-routing element 130 according to the embodiment may include operations S100 to S160. When describing FIG. 18, repeated descriptions as those given with reference to FIGS. 1 to 17 are replaced with the descriptions above with reference to FIGS. 1 to 17.

The manufacturing method of the color-routing element 130 according to one or more embodiments may generate the initial unit pattern from the latent matrix (see FIG. 7) (S100). Herein, the initial unit pattern for generating the target unit pattern of the color-routing element 130 may correspond to the initial matrix u in FIG. 7. The latent matrix may include a space with no restrictions regarding the range of the matrix and/or the correlation between adjacent points in the matrix. For example, the range of the latent matrix may be (−∞, +∞). The latent matrix may be understood as a set of matrices that are latently generated as an initial unit pattern.

The manufacturing method may include generating a reference unit pattern by performing blurring on the initial unit pattern (S110). Herein, the reference unit pattern may represent an ideal unit pattern that is generated to satisfy the minimum size condition (e.g., about 50 nm) of the target line width in the process of producing the color-routing element 130.

The manufacturing method may include performing edge detection on the reference unit pattern to generate at least one comparison unit pattern reflecting a process error (S120). The at least one comparison unit pattern may represent at least one unit pattern generated by reflecting the process error occurring during a process of producing the color-routing element 130.

In one or more embodiments, the operation of generating the at least one comparison unit pattern may include generating a first comparison unit pattern in which the reference unit pattern is dilated by adding a detected edge to each of boundary portions of the reference unit pattern.

In one or more embodiments, the operation of generating the at least one comparison unit pattern may include generating a second comparison unit pattern in which the reference unit pattern is eroded by subtracting the detected edge from each of boundary portions of the reference unit pattern.

The manufacturing method may include performing a simulation to calculate at least one color-routing figure of merit (S130). For example, the simulation device (see FIG. 7) may perform the simulation to calculate at least one color-routing figure of merit on the basis of the reference unit pattern and the at least one comparison unit pattern.

In one or more embodiments, the operation of performing the simulation may include calculating the at least one color-routing figure of merit by using the electromagnetic field simulation based on the automatic differentiation technique (see Equation 1 and Equation 2 of FIG. 7).

In one or more embodiments, the electromagnetic field simulation based on the automatic differentiation technique may include an RCWA simulation or an FDTD simulation.

In one or more embodiments, the at least one color-routing figure of merit may be calculated based on an intensity of light for each of wavelengths received at a central region of each of pixels by routing the light that has passed through the color-routing element to each of the pixels corresponding to the wavelengths. For example, the at least one color-routing figure of merit is obtained based on a first light intensity for a first wavelength received at a central region of a first pixel corresponding to the first wavelength, and a second light intensity for a second wavelength received at a central region of a second pixel corresponding to the second wavelength, by routing light that has passed through the color-routing element to the first pixel and the second pixel.

The manufacturing method may identify whether the at least one color-routing figure of merit converges (S140). When the at least one color-routing figure of merit converges, the target unit pattern may be generated based on the initial unit pattern. When the at least one color-routing figure of merit does not converge, operation S150 may be performed by the simulation device.

The manufacturing method may include calculating a gradient for at least one color-routing figure of merit (S150). For example, when the at least one color-routing figure of merit does not converge, the simulation device may calculate the gradient for the at least one color-routing figure of merit (see FIG. 7).

The manufacturing method may include generating a target unit pattern by updating the initial unit pattern based on the gradient (S160). For example, the target unit pattern may include the finally updated initial unit pattern based on the gradient.

In one or more embodiments, the operation of updating the initial unit pattern may include updating the initial unit pattern on the basis of the refractive index error and deposition thickness error of the deposition material, which occur in the film deposition process during the production process of the color-routing element.

The color-routing element 130 manufactured/produced through the manufacturing method of the color-routing element 130 according to one or more embodiments may include a spacer layer and a nanostructure array including a target unit pattern repeatedly arranged on the spacer layer and routing light, which passes through the color-routing element 130, to a pixel corresponding to each wavelength. Herein, the target unit pattern may include a unit pattern that is generated by finally updating the initial unit pattern according to the manufacturing method of the color-routing element 130 described above. For example, the target unit pattern may include a plurality of nanostructures arranged in a freeform according to a calculation result of at least one color-routing figure of merit.

In one or more embodiments, the plurality of nanostructures of the target unit pattern may include a combination of intuitively shaped nanostructures. For example, the combination of intuitively shaped nanostructures may include nanostructures having regular geometric shapes, such as polygons and circles.

In one or more embodiments, the plurality of nanostructures of the target unit pattern may include a combination of non-intuitively shaped nanostructures. For example, the non-intuitively shaped nanostructures may include nanostructures having irregular or different geometric shapes.

The image sensor including the color-routing element 130 manufactured/produced through the manufacturing method of the color-routing element 130 according to one or more embodiments may include a light detection unit including a plurality of light detection cells configured to sense light and the color-routing element 130 configured to focus the light on a light detection cell corresponding to each of wavelengths, among the plurality of light detection cells by using a nanostructure array disposed above the light detection unit. A plurality of nanostructures in the nanostructure array may be arranged in a freeform without regularity in shape, size, spacing, and arrangement, based on at least one color-routing figure of merit. The at least one color-routing figure of merit may be calculated by performing, on a reference unit pattern and at least one comparison unit pattern of the nanostructure array, an electromagnetic field simulation based on an automatic differentiation technique. Also, the at least one comparison unit pattern may represent at least one unit pattern generated by reflecting process errors that occur during the production process of the color-routing element 130. In addition, the reference unit pattern may represent a unit pattern generated to satisfy the minimum size condition (e.g., about 50 nm) of the target line width in the process of producing the color-routing element 130. Herein, the description of the color-routing element 130 in the image sensor is replaced with the description of the color-routing element 130 described above.

Therefore, according to the color-routing element 130, the method of manufacturing the same, and the image sensor including the color-routing element 130 according to one or more embodiments, the target unit pattern is manufactured based on the color-routing figure of merit and the process error, and as a result, the degree of design freedom is increased so that the plurality of nanostructures may be arranged in a free form. Accordingly, the high color-routing efficiency may be achieved, and the robustness against process errors may be obtained.

FIG. 19 is a block diagram of an electronic device including an image sensor in which a color-routing element according to one or more embodiments is utilized.

Referring to FIG. 19, a camera 2000 may include an image capturing unit 2100, an image sensor 1000, and a processor 2200.

The image capturing unit 2100 forms an optical image by focusing light reflected from an object OBJ. The image capturing unit 2100 may include an objective lens 2010, a lens driver 2120, an aperture 2130, and an aperture driver 2140. For convenience, only one lens is shown in FIG. 19, but actually, the objective lens 2010 may include a plurality of lenses having different sizes and shapes. The lens driver 2120 may communicate information about focus detection with the processor 2200 and adjust the position of the objective lens 2010 according to a control signal provided from the processor 2200. The lens driver 2120 may adjust the distance between the objective lens 2010 and the object OBJ by moving the objective lens 2010, or may adjust the positions of individual lenses in the objective lens 2010. The focus on the object OBJ may be adjusted by the lens driver 2120 that drives the objective lens 2010. This camera 2000 may be provided with an autofocus (AF) function.

The aperture driver 2140 may communicate information about the amount of light with the processor 2200 and adjust the aperture 2130 according to a control signal provided from the processor 2200. For example, the aperture driver 2140 may increase or decrease the diameter of the aperture 2130 depending on the amount of light entering the camera 2000 via the objective lens 2010 and may adjust an opening time of the aperture 2130.

The image sensor 1000 may generate an electrical image signal based on the intensity of incident light. The image sensor 1000 may include a pixel array 1100, a timing controller 1010, and an output circuit 1030. The image sensor 1000 may further include the row decoder shown in FIG. 1. The light passing through the objective lens 2010 and the aperture 2130 may form an image of the object OBJ on a light-receiving surface of the pixel array 1100. The pixel array 1100 may include a CCD or CMOS that converts optical signals into electric signals. The pixel array 1100 may include additional pixels for performing an AF function or a distance measurement function. Also, the pixel array 1100 may include the color-routing element 130 described above with reference to FIGS. 1 to 18. The color-routing element 130 manufactured through the manufacturing method of the color-routing element 130 (see FIGS. 7 and 18) according to one or more embodiments utilizes the target unit pattern manufactured based on the color-routing figure of merit and the process error. As a result, the degree of design freedom increases so that the plurality of nanostructures may be arranged, in a free form, in the target unit pattern. Accordingly, the high color-routing efficiency may be achieved, and the robustness against process errors may be obtained.

The processor 2200 may control all operations of the camera 2000 and may be provided with an image processing function. For example, the processor 2200 may provide control signals for the operation of each of components, such as the lens driver 2120, the aperture driver 2140, and the timing controller 1010.

While the inventive concept has been particularly shown and described with reference to embodiments thereof, it will be understood that various changes in form and details may be made therein without departing from the spirit and scope of the following claims.

1. A method of manufacturing a color-routing element, the method comprising:
generating an initial pattern;
performing blurring on the initial pattern to generate a reference pattern;
performing edge detection on the reference pattern to generate at least one comparison pattern reflecting a process error;
performing a simulation to obtain at least one color-routing figure of merit based on the reference pattern and the at least one comparison pattern;
updating the initial pattern based on a calculation result of the at least one color-routing figure of merit;
generating the updated initial pattern as a target pattern of the color-routing element; and
manufacturing the color-routing element based on the target pattern.

2. The method of claim 1, wherein the performing of the simulation comprises calculating the at least one color-routing figure of merit using an electromagnetic field simulation based on an automatic differentiation technique.

3. The method of claim 1, wherein the updating of the initial pattern comprises:
identifying whether the at least one color-routing figure of merit converges; and
calculating a gradient for the at least one color-routing figure of merit when the at least one color-routing figure of merit does not converge.

4. The method of claim 1,
wherein the at least one comparison pattern represents at least one pattern generated by reflecting the process error occurring during a process of producing the color-routing element, and
wherein the reference pattern represents a pattern generated to satisfy a condition of a target line width having a minimum size during the process of producing the color-routing element.

5. The method of claim 1, wherein the generating of the at least one comparison pattern comprises:
generating a first comparison pattern in which the reference pattern is dilated by adding a detected edge to boundaries of the reference pattern; and
generating a second comparison pattern in which the reference pattern is eroded by subtracting the detected edge from the boundaries of the reference pattern.

6. The method of claim 5, wherein the updating of the initial pattern comprises updating the initial pattern based on a refractive index error and a deposition thickness error of a deposition material, which occur in a film deposition process during a process of producing the color-routing element.

7. The method of claim 1, wherein the at least one color-routing figure of merit is obtained based on a first light intensity for a first wavelength received at a central region of a first pixel corresponding to the first wavelength, and a second light intensity for a second wavelength received at a central region of a second pixel corresponding to the second wavelength, by routing light that has passed through the color-routing element to the first pixel and the second pixel.

8. The method of claim 1, wherein the target pattern comprises a plurality of nanostructures disposed in a freeform without regularity in size, spacing, and arrangement.

9. The method of claim 8,
wherein the plurality of nanostructures comprise a combination of regularly shaped nanostructures or a combination of non-regularly shaped nanostructures,
wherein the combination of regularly shaped nanostructures comprises nanostructures having regular geometric shapes, such as polygons and circles, and
wherein the combination of non-regularly shaped nanostructures comprises nanostructures having different geometric shapes.

10. The method of claim 2, wherein the electromagnetic field simulation based on the automatic differentiation technique comprises a rigorous coupled wave analysis (RCWA) simulation or a finite-difference time-domain (FDTD) simulation.

11. A color-routing element comprising:
a spacer layer; and
a nanostructure array comprising a target pattern repeatedly disposed on the spacer layer and configured to route light, which passes through the color-routing element, to a pixel corresponding to a wavelength,
wherein the target pattern comprises a plurality of nanostructures disposed in a freeform based on a calculation result of at least one color-routing figure of merit.

12. The color-routing element of claim 11,
wherein the plurality of nanostructures comprise a combination of regularly shaped nanostructures, and
wherein the regularly shaped nanostructures comprise nanostructures having regular geometric shapes comprising polygons and circles.

13. The color-routing element of claim 11,
wherein the plurality of nanostructures comprise a combination of non-regularly shaped nanostructures, and
wherein the non-regularly shaped nanostructures comprise nanostructures having different geometric shapes.

14. The color-routing element of claim 11, wherein the at least one color-routing figure of merit is obtained by performing, on a reference pattern and at least one comparison pattern, an electromagnetic field simulation based on an automatic differentiation technique.

15. The color-routing element of claim 14,
wherein the at least one comparison pattern represents at least one pattern generated by reflecting a process error occurring during a process of producing the color-routing element, and
wherein the reference pattern represents a pattern generated to satisfy a condition of a target line width having a minimum size during the process of producing the color-routing element.

16. The color-routing element of claim 15,
wherein the at least one comparison pattern comprises a first comparison pattern and a second comparison pattern,
wherein the first comparison pattern represents a pattern in which the reference pattern is dilated by adding an edge to boundaries of the reference pattern, and
wherein the second comparison pattern represents a pattern in which the reference pattern is eroded by subtracting the edge from the boundaries of the reference pattern.

17. The color-routing element of claim 11,
wherein the target pattern is generated by reflecting a process error occurring during a process of producing the color-routing element, and
wherein the process error comprises a dilated error and an eroded error, which occur during a lithography process, and a refractive index error and a deposition thickness error of a deposition material, which occur during a film deposition process.

18. The color-routing element of claim 14, wherein the electromagnetic field simulation based on the automatic differentiation technique comprises a rigorous coupled wave analysis (RCWA) simulation or a finite-difference time-domain (FDTD) simulation.

19-20. (canceled)

21. An image sensor comprising:
a light detector comprising at least a first pixel configured to sense first wavelength light and a second pixel configured to sense second wavelength light; and
a color-routing element configured to:
receive light comprising at least the first wavelength light and the second wavelength light; and
using a nanostructure array, route the first wavelength light to the first pixel and route the second wavelength light to the second pixel,
wherein the nanostructure array comprises a plurality of non-regularly shaped nanostructures having different geometric shapes.
